(19) United States
(12) Patent Application Publication
(10) Pub. No.: US 2025/0232806 A1
(43) Pub. Date: Jul. 17, 2025

(54) SRAM CELL ARRAY, DRIVING METHOD AND DEVICE THEREFOR, AND PROGRAM THEREFOR

(71) Applicant: Research & Business Foundation Sungkyunkwan University, Suwon-si (KR)

(72) Inventors: Jung-Hoon CHUN, Suwon-si (KR); JUHWAN SEOK, Suwon-si (KR)

(73) Assignee: Research & Business Foundation Sungkyunkwan University, Suwon-si (KR)

(21) Appl. No.: 19/026,144

(22) Filed: Jan. 16, 2025

(30) Foreign Application Priority Data
Jan. 17, 2024 (KR) 10-2024-0007290

(51) Int. Cl. G11C 11/419

(52) U.S. Cl. CPC G11C 11/419

(57) ABSTRACT

The present invention relates to a method and device for lowering SRAM cell voltage by implementing charge sharing between a discharged bit line and floating CVDD without additional capacitors, thereby achieving efficient voltage reduction while maintaining consistent performance regardless of array size.

### CROSS-REFERENCE TO RELATED APPLICATION

This application claims the benefit of Korea Patent Application No. 10-2024-0007290 filed on Jan. 17, 2024, which are incorporated herein by reference for all purposes as if fully set forth herein.

### BACKGROUND

### Field

The present invention relates to a method for lowering the voltage (CVDD) of an SRAM cell.

### Description of Related Art

According to the conventional art, there are three methods for lowering the voltage (CVDD) of an SRAM cell.

The first method, as shown in FIG. 1, involves lowering the voltage through a voltage divider format by allowing static current flow, wherein when the EN signal becomes high, the CVDD voltage is lowered according to the strength of the PMOS and NMOS. However, this method has the disadvantage of high-power consumption due to static current flow.

The second method, as shown in FIG. 2, involves disconnecting CVDD from VDD during a pulse period and discharging it to lower the SRAM cell voltage. When the pulse signal is low, the upper PMOS turns off and disconnects CVDD from VDD. The lower PMOS turns on and lowers the CVDD voltage. However, since the pulse duration must be precisely matched to achieve the desired CVDD voltage, there is a disadvantage in that generating the pulse is difficult.

Finally, as shown in FIG. 3, there is a method of charge sharing with CVDD using an additional capacitor. This method does not have static current flow and does not require precise pulse timing. However, it has the disadvantage of increased area due to the additional capacitor required for charge sharing.

### SUMMARY

The present invention has been devised based on this technical background and aims to lower the CVDD voltage of SRAM cells through charge sharing while solving the existing problem of increased area.

According to one embodiment, an SRAM cell array comprises: SRAM cells arranged in an n*m format; wiring including bit lines, CVDD wiring, and bit line-bar for supplying signals to each column of the SRAM cells; a first PMOS transistor connecting the bit line and the CVDD wiring and a second PMOS transistor connecting the bit line-bar and CVDD for each column; a third PMOS transistor connecting VDD and the CVDD wiring; and first and second NAND gates respectively connected to the gates of the first and second PMOS transistors, receiving signals combining data or data-bar output from the write driver and a column selection signal COL with a CSBLEN signal.

According to another embodiment, a driving method for the aforementioned SRAM cell array comprises: a first step of turning off the third PMOS transistor to float the CVDD wiring; a second step of connecting the bit line and the write driver to discharge the bit line voltage; a third step of disconnecting the bit line from the write driver and connecting the CVDD wiring and the bit line for charge sharing; and a fourth step of connecting the bit line and the write driver to discharge the bit line voltage.

In the first step, the LCVEN signal is high (or 1).

In the second step, when the CSBLEN signal is low, the WM voltage becomes VDD and the bit line and write driver are connected through the write mux.

In the third step, after the bit line voltage is discharged, the CSBLEN voltage becomes VDD, causing the WM signal to become low and disconnecting the bit line from the write driver.

In the fourth step, when charge sharing ends, the CSBLEN voltage becomes 0 and the WM voltage becomes VDD, reconnecting the bit line and the write driver.

Another embodiment of the present invention discloses a computing device and a recording medium storing a program coded to be executable by a computer implementing the aforementioned method.

In the present invention, to write data 0, the voltage of the SRAM cell is lowered by charge sharing between the discharged bit line and the floating SRAM cell voltage. Using this method can alleviate the area problem that was a disadvantage of the conventional method using additional capacitors. Additionally, it maintains the advantages of the conventional charge sharing method where there is no static current flow and no need for precise pulse signals. Finally, it has the advantage that even when the size of the SRAM array changes, it maintains consistent performance because the capacitor ratio between the bit line and CVDD remains constant.

### BRIEF DESCRIPTION OF THE DRAWING

The accompanying drawings, which are included to provide a further understanding of the present disclosure and constitute a part of the detailed description, illustrate embodiments of the present disclosure and serve to explain technical features of the present disclosure together with the description.

FIGS. 1 to 3 show conventional technology.

FIG. 4 shows an example of circuit configuration of an SRAM cell used in the present invention.

FIG. 5 shows the wiring relationship between the write driving unit and the SRAM cell array according to the present invention.

FIGS. 6 to 10 show waveforms of each signal according to driving voltage (VDD) in chronological order during data writing.

FIG. 11 is a block diagram of a driving device according to the present invention.

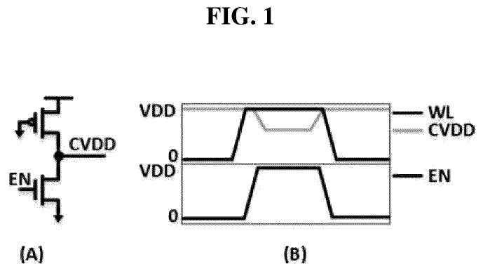

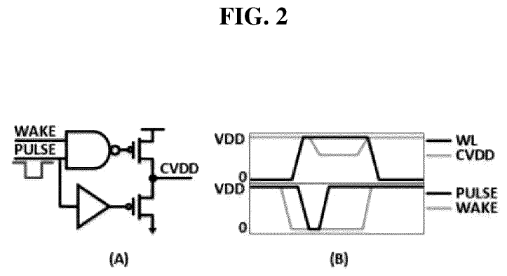

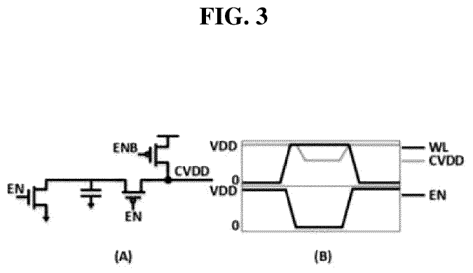

### DETAILED DESCRIPTION

Hereinafter, embodiments of the present invention will be described in detail with reference to the drawings. However, detailed descriptions of known functions or configurations that might obscure the gist of the present invention are omitted. Additionally, throughout the specification, when a component is described as “comprising” something, unless specifically stated otherwise, this does not exclude other components but means that other components may be further included.

Furthermore, terms such as “first,” “second,” etc. may be used to describe various components, but these components should not be limited by these terms. These terms are used only to distinguish one component from another component.

Terms used in this specification are used only to describe specific embodiments and are not intended to limit the present invention. Singular expressions include plural expressions unless the context clearly dictates otherwise. Throughout this application, terms such as “comprise” or “include” specify the presence of stated features, numbers, steps, operations, components, elements, or combinations thereof, but do not preclude the presence or addition of one or more other features, numbers, steps, operations, components, elements, or combinations thereof.

Unless specifically defined otherwise, all technical and scientific terms used herein have the same meaning as commonly understood by one of ordinary skill in the relevant art. Common terms as defined in general dictionaries should be interpreted as having meanings consistent with their meaning in the context of the relevant art and should not be interpreted in an idealized or overly formal sense unless expressly defined herein.

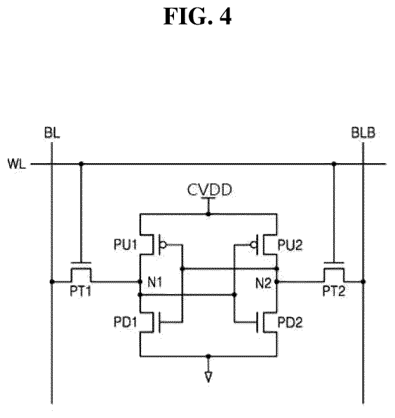

FIG. 4 is an equivalent circuit diagram showing an example SRAM cell used in the present invention.

Referring to FIG. 4, the SRAM cell includes multiple transistors connected to a pair of bit lines (BL, BLB) or a word line (WL), and the multiple transistors include a pair of transfer transistors (PT1, PT2), a pair of pull-up transistors (PU1, PU2), and a pair of pull-down transistors (PD1, PD2). The first and second pull-up transistors (PU1, PU2) are PMOS transistors, and the first and second pull-down transistors (PD1, PD2) and first and second transfer transistors (PT1, PT2) are NMOS transistors.

The gates of the first and second transfer transistors (PT1, PT2) are connected to the word line (WL), and their drains are respectively connected to the pair of bit lines (BL, BLB). The sources of the first and second pull-up transistors (PU1, PU2) are connected to the cell power line (CVDD), and the sources of the first and second pull-down transistors (PD1, PD2) are connected to the ground line (GND). The source of the first transfer transistor (PT1), drain of the first pull-up transistor (PU1), and drain of the first pull-down transistor (PD1) are commonly connected at a first node (N1). The source of the second transfer transistor (PT2), drain of the second pull-up transistor (PU2), and drain of the second pull-down transistor (PD2) are commonly connected at a second node (N1). The gate of the first pull-up transistor (PU1) and the gate of the first pull-down transistor (PD1) are commonly connected to the second node (N2) to form a first latch. The gate of the second pull-up transistor (PU2) and the gate of the second pull-down transistor (PD2) are commonly connected to the first node (N1) to form a second latch.

Here, when the first node (N1) is at a high level, the second pull-up transistor (PU2) turns off and the second driving transistor (PD2) turns on, causing the second node (N2) to become low level. As the second node (N2) changes to low level, the first pull-up transistor (PU1) turns on and the second pull-down transistor (PD1) turns off, maintaining the first node (N1) at high level.

When the second node (N2) is at high level, the first pull-up transistor (PU1) turns off and the first pull-down transistor (PD1) turns on, causing the first node (N1) to become low level. When the first node (N1) becomes low level, the second pull-up transistor (PU2) turns on and the second pull-down transistor (PD2) turns off, maintaining the second node (N2) at high level.

Therefore, when the first and second transfer transistors (PT1, PT2) turn on based on the driving signal applied to the word line (WL), data signals provided to the bit lines (BL, /BL) are latched to the first and second nodes (N1, N2) through the first and second transfer transistors (PT1, PT2).

On the other hand, when the first and second transfer transistors (PT1, PT2) turn on, the data latched at the first and second nodes (N1, N2) is provided to the bit lines (BL, /BL) through the first and second transfer transistors (PT1, PT2). Accordingly, the signals provided to the bit lines (BL, /BL) are sensed through a sense amplifier (not shown) to read the data latched at the first and second nodes (N1, N2).

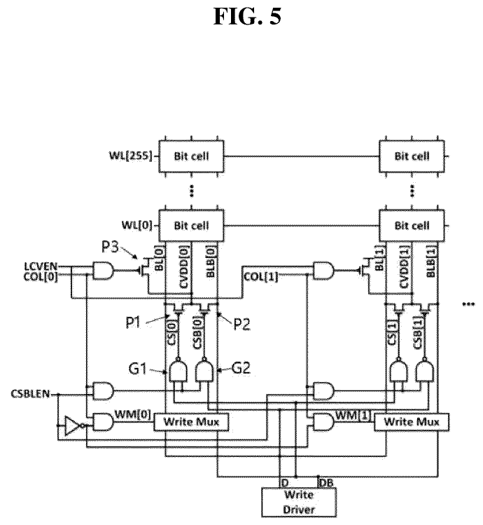

FIG. 5 shows the wiring relationship of the SRAM cell array. The array has signal lines arranged to supply necessary signals to the SRAM cell columns, and the signal lines are connected by multiple NAND gates and AND gates. The signal lines are wirings for supplying signals explained through Table 1, and the wiring explanation is substituted by the explanation of FIG. 5 and Table 1.

The SRAM cell array of the present invention includes a first PMOS transistor (P1) connecting the bit line (BL) and CVDD and a second PMOS transistor (P2) connecting the bit line-bar (BLB) and CVDD for charge sharing, and a third PMOS transistor (P3) connecting VDD and CVDD.

Further, each PMOS transistor (P1, P2) gate is connected to respective NAND gates (G1, G2) that receive signals combining data (D) or data-bar (DB) output from the write driver and a column selection signal COL with CSBLEN signal.

Through this configuration, while maintaining the advantages of the conventional charge sharing method—no static current and no need for precise pulses—the area penalty is minimized by not using additional capacitors. Additionally, since the CVDD voltage value is determined by charge sharing between the bit line and CVDD, it demonstrates consistent performance even when the SRAM array size changes.

Furthermore, since the connection between the bit line and write driver must be disconnected during the charge sharing period, the write mux input is also controlled using CSBLEN and COL signals.

The signal abbreviations used in FIG. 5 and this specification are shown in Table 1.

TABLE 1

| | |
|---|---|
| WL | Word line |
| BL/BLB | Bit line/Bit line-bar |
| LCVEN | Lower Cell VDD Enable (Signal to disconnect PMOS |
| | connected to CVDD to lower CVDD voltage) |
| CSBLEN | Charge Sharing Bitline Enable (Signal to connect PMOS |
| | connecting BL and CVDD by turning off Write mux that |
| | connects Write driver and BL) |
| WM | Write Mux |
| CS/CSB | Charge Sharing/Charge Sharing-bar (Signal for On/Off |
| | PMOS to perform charge sharing between BL and CVDD) |
| CVDD | Cell VDD |
| COL | Signal for selecting Column |
| D/DB | Data/Data-bar |

Hereinafter, the driving method of the present invention will be explained with reference to FIG. 5.

As a premise for explanation, assume that data 0 is to be written to the bit line (BL) of column 0 in FIG. 5. Since column 0 is selected, COL[0] voltage is VDD, while COL[1] voltage is 0. The write operation begins when the WL voltage of the selected SRAM cell becomes VDD.

When LCVEN signal becomes high (1), the CVDD of the column for write operation enters a floating state. When CSBLEN signal is low (0), WM[0] voltage becomes VDD, and the bit line and write driver are connected through the write mux, causing the bit line voltage to discharge to 0.

After the bit line voltage is discharged to 0, CSBLEN voltage becomes VDD, causing WM[0] signal to become low and disconnecting the bit line from the write driver. At this time, CS[0] becomes low, connecting CVDD [0] and the bit line for charge sharing. Consequently, CVDD [0] voltage drops.

When charge sharing ends, CSBLEN voltage becomes 0 again and WM[0] voltage becomes VDD, reconnecting the bit line and write driver. The bitline is discharged to 0 again, and data 0 is written to the selected SRAM cell. When the write operation ends, the wordline voltage becomes 0 and LCVEN voltage becomes 0, causing CVDD [0] voltage to become VDD.

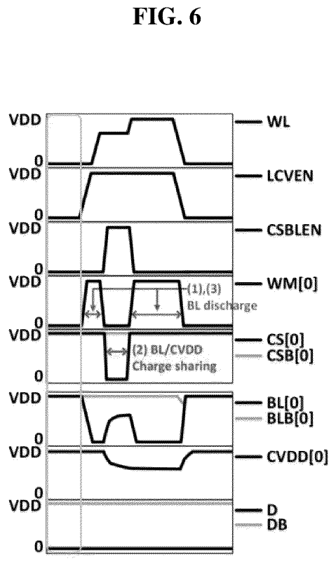

Hereinafter, the detailed operating states of the aforementioned driving method will be explained using FIGS. 6 to 10. FIGS. 6 to 10 show the waveforms of each signal in chronological order during data writing. In one example, the driving method includes states 1 through 5 in chronological order.

As shown in FIG. 6, the signal states and corresponding operations in State 1 are as follows:

WL=0: Initial state where no reading/writing is occurring.

LCVEN=0: Since the AND gate output is 0, CVDD is connected to VDD through P3.

CSBLEN=0: Since the AND gate output is 0, CS[0] and CSB[0] from G1, G2 outputs are VDD.

WM[0]=0: Write mux is in off state.

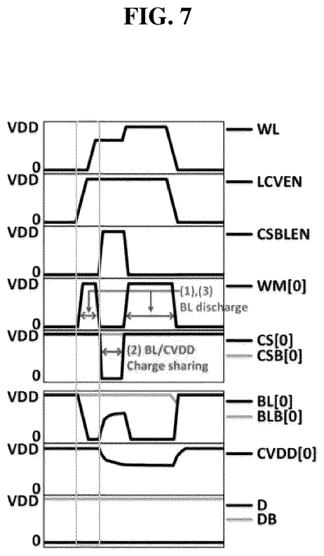

As shown in FIG. 7, the signal states and corresponding operations in State 2 are as follows:

WL=VDD: Writing begins.

COL[0]=VDD: Column 0 selected.

LCVEN=VDD: Since AND gate output is VDD, P3 does not operate and CVDD is floated.

CSBLEN=0: Since AND gate output is 0, CS[0] and CSB[0] from G1, G2 outputs remain VDD.

WM[0]=VDD: Since COL0 and CSBLEN inverter output (=0) are connected to AND gate, write mux turns on.

With D=0, DB=VDD, and connection through write mux, BL[0]-0 is discharged and BLB=VDD.

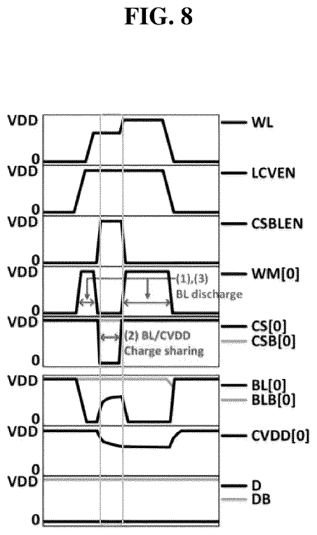

As shown in FIG. 8, the signal states and corresponding operations in State 3 are as follows:

WL=VDD: Writing in progress.

COL[0]=VDD: Column 0 selected.

LCVEN=VDD: Since AND gate output is VDD, P3 does not operate and CVDD maintains floating state.

CSBLEN=VDD: Since AND gate output is VDD, AND gate output is provided to G1, G2 inputs.

WM[0]=0: Since COL0 and CSBLEN inverter output (=0) are connected to AND gate, write mux turns off.

CS[0]=0: Since DB=VDD, G1's output CS becomes 0, and BL[0] and CVDD [0] connect through P1.

CSB[0]=VDD: Since D=0, G2's output CSB is VDD.

In this State 3, as charge sharing occurs, CVDD voltage drops and BL[0] voltage rises.

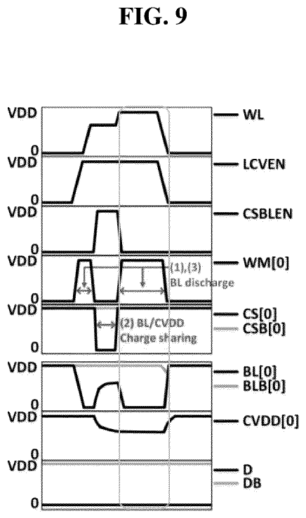

As shown in FIG. 9, the signal states and corresponding operations in State 4 are as follows:

WL=VDD: Writing in progress.

COL[0]=VDD: Column 0 selected.

LCVEN=VDD: Since AND gate output is VDD, P3 does not operate and CVDD maintains floating state.

CSBLEN=0: Since AND gate output is 0, AND gate outputs CS[0], CSB[0] become VDD.

WM[0]=VDD: Since COL0 and CSBLEN inverter output (=VDD) are connected to AND gate, write mux turns on.

With D=0, DB=VDD, and connection through write mux, BL[0]=0, BLB=VDD.

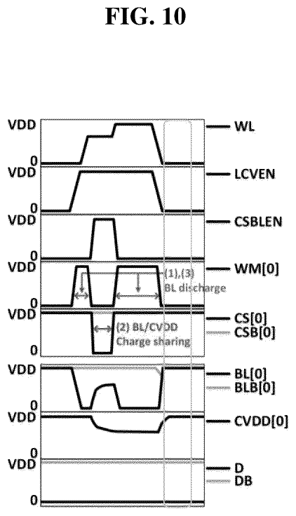

As shown in FIG. 10, the signal states and corresponding operations in State 5 are as follows:

WL=0: Reading/writing stopped.

LCVEN=0: Since AND gate output is 0, CVDD is connected to VDD through P3, thus CVDD=VDD.

CSBLEN=0: Since AND gate output is 0, AND gate outputs CS[0], CSB[0] are VDD. WM[0]-0: Write mux off

BL[0], BLB[0]=VDD: VDD when not reading/writing.

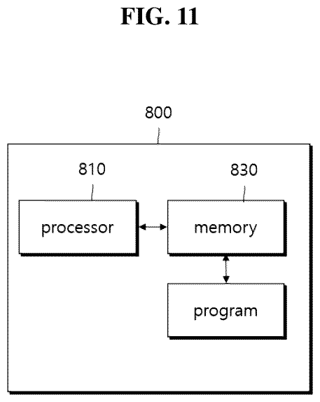

Meanwhile, explaining the driving device according to the aforementioned driving method, the driving device in FIG. 11 is a reconfiguration of the above series of configurations from a hardware perspective. Therefore, to avoid redundancy, only an overview of each configuration's function and operation will be briefly described here.

The driving device (800) includes a memory (810) storing a program compiled into computer-readable language for implementing the driving method of the aforementioned SRAM cell array, and a processor (830) executing the program.

The SRAM cell array includes SRAM cells arranged in n*m format, wiring including bit lines, CVDD wiring, and bit line-bar for supplying signals to each column of the SRAM cells, a first PMOS transistor connecting the bit line and the CVDD wiring and a second PMOS transistor connecting the bit line-bar and CVDD for each column, a third PMOS transistor connecting VDD and CVDD wiring, first and second NAND gates respectively connected to the gates of the first and second PMOS transistors and receiving signals combining data or data-bar output from write driver with a column selection signal COL and CSBLEN signal, and the driving method comprises: a first step of turning off the third PMOS transistor to float the CVDD wiring, a second step of connecting the bit line and the write driver to discharge the bit line voltage, a third step of disconnecting the bit line from the write driver and connecting the CVDD wiring and the bit line for charge sharing, and a fourth step of connecting the bit line and the write driver to discharge the bit line voltage.

In the first step, LCVEN signal is high (or 1).

In the second step, when CSBLEN signal is low, WM voltage becomes VDD and the bit line and write driver are connected through write mux.

In the third step, after the bitline voltage is discharged, CSBLEN voltage becomes VDD, causing WM signal to become low and disconnecting the bitline from the write driver.

In the fourth step, when charge sharing ends, CSBLEN voltage becomes 0 and WM voltage becomes VDD, reconnecting the bitline and the write driver.

Meanwhile, the driving method of the present invention can be implemented as a code in a recording medium readable by computer. The computer-readable recording medium includes all kinds of recording devices in which data readable by computer systems is stored.

Examples of computer-readable recording media include ROM, RAM, CD-ROM, magnetic tapes, floppy disks, optical data storage devices. Also, the computer-readable recording medium can be distributed in networked computer systems, where computer-readable code can be stored and executed in a distributed manner.

While the present invention has been described in terms of its various embodiments as described above, those skilled in the art will recognize that the present invention can be practiced with modification within the spirit and scope of the appended claims. Therefore, the disclosed embodiments should be considered illustrative and not restrictive. The scope of the present invention is not determined by the above description but by the appended claims, and all differences within the scope equivalent to the claims are to be construed as being included in the present invention.

What is claimed is:

1. An SRAM cell array comprising:
SRAM cells arranged in an n*m format (where n and m are natural numbers);
wiring including bit lines, CVDD wiring, and bit line-bar for supplying signals to each column of the SRAM cells;
for each column, a first PMOS transistor connecting the bit line and the CVDD wiring and a second PMOS transistor connecting the bit line-bar and CVDD;
a third PMOS transistor connecting VDD and the CVDD wiring;
first and second NAND gates respectively connected to gates of the first and second PMOS transistors and receiving signals combining data or data-bar output from a write driver with a column selection signal COL and CSBLEN signal.

2. A driving method for the SRAM cell array including SRAM cells arranged in an n*m format (where n and m are natural numbers); wiring including bit lines, CVDD wiring, and bit line-bar for supplying signals to each column of the SRAM cells; for each column, a first PMOS transistor connecting the bit line and the CVDD wiring and a second PMOS transistor connecting the bit line-bar and CVDD; a third PMOS transistor connecting VDD and the CVDD wiring; first and second NAND gates respectively connected to gates of the first and second PMOS transistors and receiving signals combining data or data-bar output from a write driver with a column selection signal COL and CSBLEN signal, comprising:
a first step of turning off the third PMOS transistor to float the CVDD wiring;
a second step of connecting the bit line and the write driver to discharge the bit line voltage;
a third step of disconnecting the bit line from the write driver and connecting the CVDD wiring and the bit line for charge sharing;
a fourth step of connecting the bit line and the write driver to discharge the bit line voltage.

3. The driving method of claim 2, wherein in the first step, LCVEN signal is high.

4. The driving method of claim 2, wherein in the second step, when CSBLEN signal is low, WM voltage becomes VDD and the bit line and the write driver are connected through write mux.

5. The driving method of claim 2, wherein in the third step, after the bit line voltage is discharged, CSBLEN voltage becomes VDD, causing WM signal to become low and disconnecting the bit line from the write driver.

6. The driving method of claim 2, wherein in the fourth step, when charge sharing ends, CSBLEN voltage becomes 0 and WM voltage becomes VDD, reconnecting the bit line and the write driver.

7. A non-transitory recording medium storing a program coded to be executable by a computer, the program implementing the driving method of claim 2.

8. A driving device comprising:
a memory storing a driving method for an SRAM cell array; and a processor executing the driving method; wherein the SRAM cell array comprises:
SRAM cells arranged in an n*m format (where n and m are natural numbers);
wiring including bit lines, CVDD wiring, and bit line-bar for supplying signals to each column of the SRAM cells;
for each column, a first PMOS transistor connecting the bit line and the CVDD wiring and a second PMOS transistor connecting the bit line-bar and CVDD;
a third PMOS transistor connecting VDD and CVDD wiring;
first and second NAND gates respectively connected to gates of the first and second PMOS transistors and receiving signals combining data or data-bar output from a write driver with a column selection signal COL and CSBLEN signal.

9. The driving device of claim 8, wherein in the first step, LCVEN signal is high.

10. The driving device of claim 8, wherein in the second step, when CSBLEN signal is low, WM voltage becomes VDD and the bit line and the write driver are connected through write mux.

11. The driving device of claim 8, wherein in the third step, after the bit line voltage is discharged, CSBLEN voltage becomes VDD, causing WM signal to become low and disconnecting the bit line from the write driver.

12. The driving device of claim 8, wherein in the fourth step, when charge sharing ends, CSBLEN voltage becomes 0 and WM voltage becomes VDD, reconnecting the bit line and the write driver.
